(19) United States
(12) Patent Application Publication
(10) Pub. No.: US 2023/0178495 A1
(43) Pub. Date: Jun. 8, 2023

(54) WIRE STRUCTURE, WIRE STRUCTURE FORMATION METHOD, AND ELECTRONIC APPARATUS

(71) Applicant: SHINKAWA LTD., Tokyo (JP)

(72) Inventor: Sunki Park, Tokyo (JP)

(73) Assignee: SHINKAWA LTD., Tokyo (JP)

(21) Appl. No.: 17/921,351

(22) PCT Filed: Dec. 21, 2020
(86) PCT No.: PCT/JP2020/047715

§ 371 Date: Oct. 25, 2022

(51) Int. Cl. H01L 23/552; H01L 25/16; H01L 21/48

(52) U.S. Cl. CPC H01L 23/552; H01L 25/16; H01L 21/4896

(57) ABSTRACT

A wire structure (50A) includes: a column-like bump (45), provided to be adjacent to a second electronic component (32b) installed on a substrate (31); and a looping wire (50), bonded onto the substrate (31) to stride over the second electronic component (32b). The looping wire (50) includes: a second raised part (54), wherein a tip is bonded to the substrate (31) on a side of the column-like bump (45) opposite to the second electronic component (32b) to be raised from the substrate (31); a loop part (55), extending to stride over the second electronic component (32b); and a bent part (56), bent to be engaged with an upper end of the column-like bump (45) to connect the loop part (55) and the second raised part (54).

### TECHNICAL FIELD

The invention relates to a configuration of a wire structure including a column-like bump and a looping wire which loops to stride over an electronic component and a wire structure formation method.

### RELATED ART

It has been proposed (see, for example, Patent Literature 1), to form a wire striding over an electronic component, such as a semiconductor chip, through wire bonding, and configure electromagnetic shielding.

In the case of forming a looping wire striding over an electronic component by using the method described in Patent Literature 1, at a bonding start point side end, the wire can be raised vertically in a state in which the tip of the wire is bonded onto a substrate, and curved laterally at a large angle. Therefore, even if the bonding start point is arranged close to the electronic component, the wire does not come into contact with the electronic component. However, at a bonding end point side, since it is difficult to bend the looping wire toward the substrate, it is necessary to set the bonding end point to be away from the electronic component (see para. 0013 of Patent Literature 1). Therefore, in the case of forming a looping wire striding over an electronic component by using the method of Patent Literature 1, a wide looping wire formation space is required, and an issue that the size of the electronic apparatus is increased arises.

### CITATION LIST

### Patent Literature

[Patent Literature 1] Japanese Laid-open No. 2020-25076

### SUMMARY OF INVENTION

### Technical Problem

Therefore, an objective of the invention is to provide a wire structure enabling magnetic shielding for an electronic component by using less space.

### Solution to Problem

A wire structure according to the invention includes a column-like bump, provided to be adjacent to an electronic component installed on a substrate; and a looping wire, bonded onto the substrate to stride over the electronic component. The looping wire includes: a raised part, wherein a tip is bonded to the substrate on a side of the column-like bump opposite to the electronic component to be raised from the substrate; a loop part, extending to stride over the electronic component; and a bent part, bent to be engaged with an upper end of the column-like bump to connect the loop part and the raised part

Accordingly, the bent part is engaged with the upper end of the column-like bump to be bent. Therefore, the bent angle of the bent large can be increased, and the raised part can be raised from the substrate at a nearly vertical angle. Accordingly, even if the tip of the raised part is bonded to a position adjacent to the electronic component, the upper part of the raised part or the bent part can be suppressed from contacting the electronic component, and the wire structure enabling magnetic shielding for the electronic component can be provided by using less space.

In the wire structure of the invention, an upper end of the column-like bump may have a groove extending in an extending direction of the loop part, and the bent part may be engaged with the groove.

Accordingly, the bent part can be stabilized to be engaged with the upper end of the column-like bump, and a bent part with a large bent angle can be set stably.

In the wire structure of the invention, the bent part may have a bent angle ranging from 60° to 90°

Accordingly, the raised part can be raised from the substrate at a nearly vertical angle, and a compact wire structure can be formed.

In the wire structure of the invention, a height of the column-like bump may be 50% or more of a height from the substrate to the loop part

Accordingly, the raised part or the bent part can be more reliably suppressed from contacting the electronic component.

A wire structure formation method is a wire structure formation method for forming a wire structure including a column-like bump and a looping wire by using a bonding tool. The wire structure formation method includes: a column-like bump formation process of folding multiple times and pressing a wire, by using the bonding tool, to a bump point on a substrate to form a column shape, thereby forming the column-like bump; a first bonding process of bonding the wire, by using the bonding tool, onto a first bond point arranged on the substrate to sandwich an electronic component with the bump point; a kink wire formation process of, after the first bonding process, raising the bonding tool to unwind the wire from a tip of the bonding tool, and moving the bonding tool laterally to form a kink wire comprising at least one kink; a loop part formation process of, after the kink wire formation process, looping the bonding tool toward an upper end of the column-like bump to form a loop part striding over the electronic component between the first bond point and the upper end of the column-like bump; a bent part formation process of, after the loop part formation process, engaging a side surface of the kink wire to the upper end of the column-like bump to bend the kink wire toward the substrate, thereby forming a bent part; and a raised part formation process of, after the bent part formation process, bonding the kink wire, by using the bonding tool, to a second bond point adjacent to a side opposite to the first bond point with respect to the bump point and provided on the substrate, and forming a raised part raised from the second bond point to be connected with the bent part.

Accordingly, after the column-like bump is formed, the bonding tool loops until the upper end of the column-like bump to engage the side surface of the kink wire with the upper end of the column-like bump. Therefore, a bent part with a large bent angle can be formed, and the raised part can be raised at a nearly vertical angle from the substrate. Accordingly, even if the tip of the raised part is bonded to a position adjacent to the electronic component, the upper part of the raised part or the bent part can be suppressed from contacting the electronic component, and the wire structure enabling magnetic shielding for the electronic component can be formed by using less space.

In the wire structure of the invention, the bonding tool may be a capillary including a through hole into which the wire is inserted and a ring-shaped face part provided on a periphery of the through hole. In the column-like bump formation process, at a time of folding a side surface of the wire to form a folded part of an uppermost segment, a center position of the capillary may be deviated in a direction intersecting with an extending direction of the loop part to press the side surface of the wire by using the face part, and a groove extending in the extending direction of the loop part may be formed at the upper end of the column-like bump

Accordingly, by deviating the center position of the capillary in a direction intersecting with the extending direction of the loop part to press the side surface of the wire by using the face part, the groove extending in the extending direction of the loop part can be simply formed at the upper end of the column-like bump.

In the wire structure formation method of the invention, in the bent part formation process, a side surface of the kink wire may be engaged with the groove to bend the kink wire toward the substrate by using the bonding tool.

Accordingly, the bent part can be stabilized to be engaged with the upper end of the column-like bump, and a bent part with a large bent angle can be formed stably.

In the wire structure formation method of the invention, ball-bonding may be performed on the wire at the first bond point in the first bonding process, and stitch-bonding may be performed at the second bond point in the raised part formation process.

In the wire structure formation method of the invention, in the column-like formation process, another column-like bump may be further formed at another bump point arranged between the first bond point and the electronic component. In addition, in the loop part formation process, after the kink wire formation process, when the bonding tool loops toward the upper end of the column-like bump to form the loop part striding over the electronic component between the first bond point and the upper end of the column-like bump, a side surface of the kink wire may be engaged with an upper end of the another column-like bump to bend the kink wire toward a top of the electronic component, thereby forming another bent part.

Accordingly, the space for forming the wire structure on the first bond point side can be reduced, and a wire structure enabling magnetic shielding for the electronic component can be formed by using less space.

An electronic apparatus according to the invention includes: a substrate; an electronic component installed on the substrate; a column-like bump, provided to be adjacent to the electronic component; and a looping wire, bonded onto the substrate to stride over the electronic component. The looping wire includes: a raised part, wherein a tip is bonded to the substrate on a side of the column-like bump opposite to the electronic component to be raised from the substrate; a loop part, extending to stride over the electronic component; and a bent part, bent to be engaged with an upper end of the column-like bump to connect the loop part and the raised part

Accordingly, the electronic apparatus can be miniaturized.

In the electronic apparatus of the invention, an upper end of the column-like bump may have a groove extending in an extending direction of the loop part, and the bent part may be engaged with the groove.

### Effects of Invention

The invention is capable of providing a wire structure enabling magnetic shielding for an electronic component by using less space.

### BRIEF DESCRIPTION OF DRAWINGS

FIG. 1 is a plan view of an electronic apparatus including a wire structure according to an embodiment.

FIG. 2 is a cross-sectional view of the electronic apparatus including the wire structure of the embodiment and taken along an A-A cross-sectional line shown in FIG. 1.

FIG. 3 is a perspective view illustrating details of a B part shown in FIG. 2.

FIG. 4 is a perspective view illustrating a column-like bump of the wire structure of the embodiment when viewed from D-D shown in FIG. 3.

FIG. 5 is a perspective view illustrating details of a part C shown in FIG. 2.

FIG. 6 is a perspective view illustrating a configuration of a wire bonding apparatus used for manufacturing the electronic apparatus including the wire structure of the embodiment.

FIG. 7 is a cross-sectional view of a capillary attached to the wire bonding apparatus shown in FIG. 1.

FIG. 8 is a view illustrating an operation of a tip of the capillary at a time when a press-bonded ball and a folded part of the column-like bump are formed on a second pad.

FIG. 9A is a view illustrating a molding process of an air free ball at a time when the column-like bump is formed by using the wire bonding apparatus shown in FIG. 6.

FIG. 9B is a view illustrating a state in which ball-bonding is performed to form the press-bonded ball when the column-like bump is formed by using the wire bonding apparatus shown in FIG. 6.

FIG. 9C is a view illustrating a state in which the capillary is raised from the state shown in FIG. 9B.

FIG. 9D is a view illustrating a state in which the capillary is moved laterally rightward from the state shown in FIG. 9C.

FIG. 9E is a view illustrating a state in which the capillary is raised from the state shown in FIG. 9D. FIG. 9F is a view illustrating a state in which the capillary is moved laterally leftward and a face part on the right side is located immediately above a ball neck from the state shown in FIG. 9E.

FIG. 9G is a view illustrating a state in which a side surface of a wire is pressed onto the ball neck to form a crushed part by using the face part on the right side of the capillary.

FIG. 9H is a view illustrating a state in which the capillary is raised from the state of FIG. 9G.

FIG. 9I is a view illustrating a state in which the capillary is moved laterally rightward and the face part on the left side is located immediately above the crushed part from the state shown in FIG. 9H.

FIG. 9J is a view illustrating a state in which the side surface of the wire is pressed onto the crushed part to form the folded part by using the face part on the left side of the capillary.

FIG. 9K is a perspective view illustrating a state in which, after the state shown in FIG. 9J, the capillary is raised, and the side surface of the wire is alternately folded multiple times from the left and the right to form a column shape, and the side surface of the wire is pressed to the upper end to form a column-like bump having a groove extending in a front-rear direction by using the face part on the left side of the capillary.

FIG. 9L is a view illustrating a state in which, from the state of FIG. 9K, a wire clamper and the capillary are raised and a wire tail extends from the tip of the capillary, and then in a state in which the wire clamper is closed, the clamper and the capillary are further raised to separate the wire tail from the column-like bump.

FIG. 10 is a view illustrating a movement of the tip of the capillary in a case where a kink wire is formed on a press-bonded ball formed on a first pad.

FIG. 11A is a perspective view illustrating the kink wire and the press-bonded ball formed on the first pad.

FIG. 11B is a view illustrating a state in which, from the state of FIG. 11A, the tip of the capillary loops toward the column-like bump to form a first raised part and a loop part.

FIG. 11C is a perspective view illustrating a detailed view of a part E of FIG. 11B.

FIG. 11D is a perspective view illustrating a state in which, from the state shown in FIGS. 11B and 11C, the tip of the capillary is moved downward in an arc shape toward a second bond point to form a bent part.

FIG. 11E is a perspective view illustrating a state in which, from the state of FIG. 11D, the tip of the capillary is lowered to be stitch-bonded onto the second pad to form the bent part, a second raised part, and a stitch-bonded part.

FIG. 11F is a perspective view illustrating a detailed view of a part F of FIG. 11E.

FIG. 12 is a perspective view illustrating a first raised part of a wire structure according to another embodiment.

### DESCRIPTION OF EMBODIMENTS

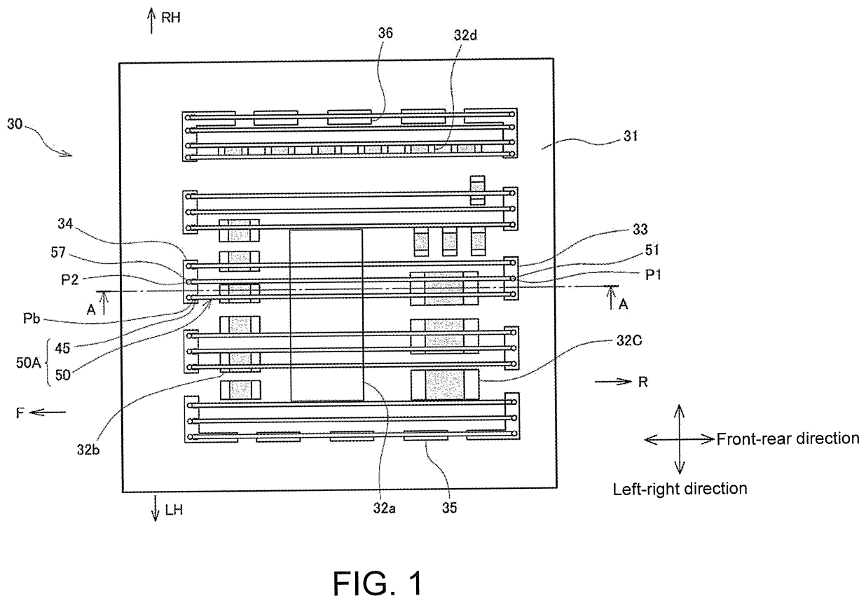

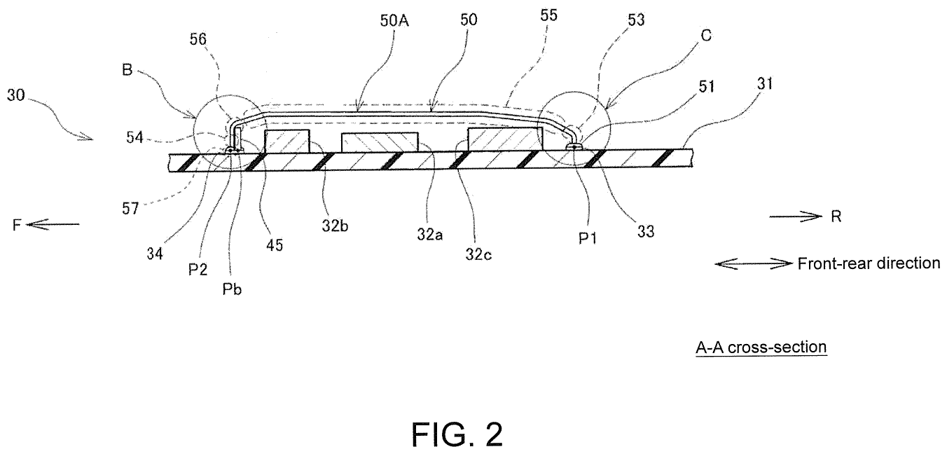

In the following, an electronic apparatus 30 according to an embodiment is described with reference to the drawings. As shown in FIGS. 1 and 2, an electronic apparatus 30 includes a substrate 31, first to fourth electronic components 32a to 32d installed onto the substrate 31, a column-like bump 45, and a looping wire 50. The column-like bump 45 and the looping wire 50 form a wire structure 50A according to the embodiment.

The first electronic component 32a is installed to the center of the substrate 31. The first electronic component 32a may be, for example, a semiconductor chip or an IC. In addition, the second and third electronic components 32b and 32c are installed on the sides of the first electronic component 32a. The second and third electronic components 32b and 32c may be, for example, a capacitor or an inductor. In addition, the fourth electronic component 32d is installed. The fourth electronic component 32d may be, for example, a resistor, etc.

On the front surface of the substrate 31 around the peripheries of the first to fourth electronic components 32a to 32d, a first pad 33, a second pad 34, a left-side pad 35, and a right side pad 36 formed by metal are provided. A first bond point P1 of the looping wire 50 is arranged at the first pad 33. In addition, a second bond point P2 of the looping wire 50 and and a bump point Pb forming the column-like bump 45 are arranged at the second pad 34. The second bond point P2 is arranged on a side opposite to the first bump point P1 or the second electronic component 32b with respect to the bump point Pb. In addition, the bump point Pb and the first bond point P1 are arranged on the substrate 31 to sandwich the first to fourth electronic components 32a to 32d.

In the following description, a direction from the first bond point P1 to the second bond point P2 is set as a forward direction (front), a direction from the first bond point P1 to a side opposite to the second bond point P2 is set as a rearward direction (rear), the left side along the forward direction is set as the left side, and the right side along the forward direction is set as the right side. In addition, an extending direction of the first bond point P1 and the second bond point P2 is set as the front-rear direction, and a direction orthogonal to the front-rear direction is set as the left-right direction in the descriptions. Moreover, in the respective figures, a symbol “F” indicates the front, a symbol “R” indicates the rear, a symbol “LH” indicates the left side, and a symbol “RH” indicates the right side.

As shown in FIGs, 2 and 3, the column-like bump 45 is formed at the bump point Pb arranged on a side (the rear side) of the third electronic component 32b on the second pad 34. The column-like bump 45 is a bump in a column shape formed to be adjacent to the third electronic component 32b.

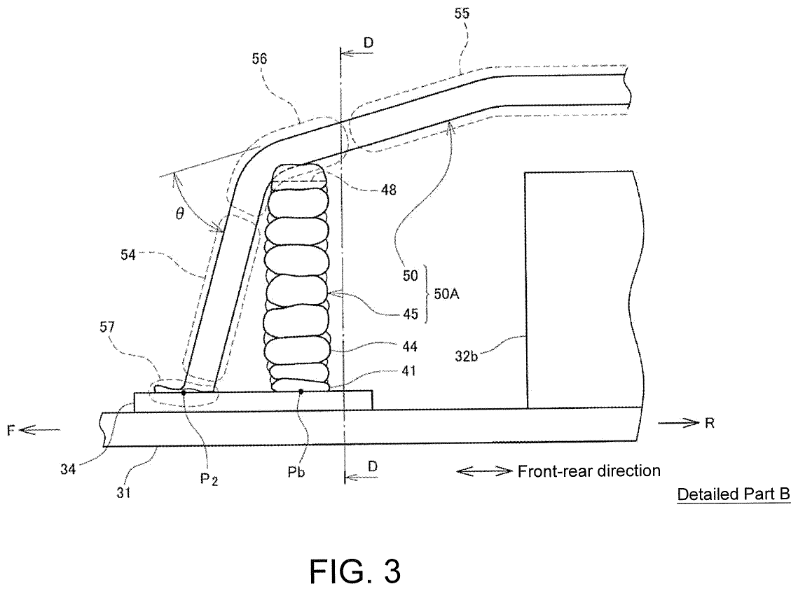

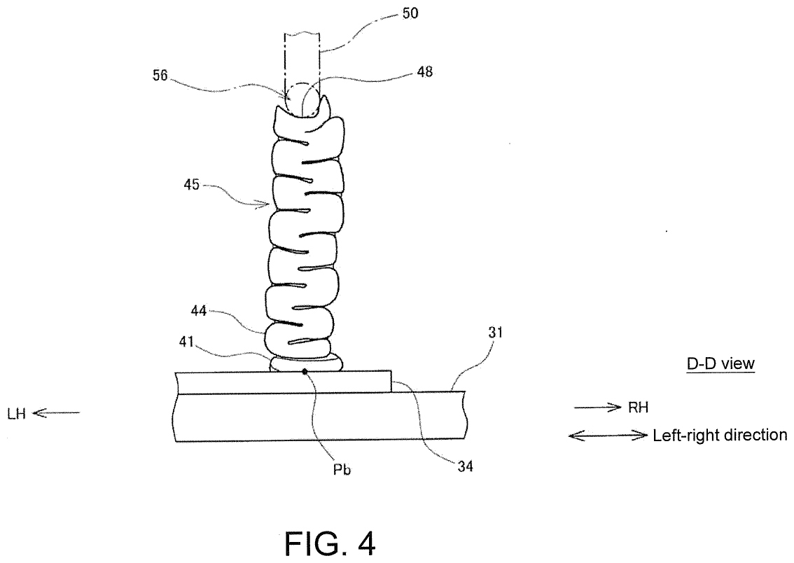

As shown in FIGS. 3 and 4, the column-like bump 45 includes a press-bonded ball 41 and multiple folded parts 44 As shown in FIG. 4, the column-like bump 45 is in a column shape in which the folded parts 44 are formed in multiple segments by alternately folding the side surface of a wire 16 multiple times from the left to the right on the press-bonded ball 41 formed on the second pad 34. On the upper end of the column-like bump 45, a groove 48 extending in the front-rear direction is formed. Since the looping wire 50 is bonded to the first bond point P1 and the second bond point P2 of the substrate 31 to extend in the front-rear direction, the groove 48 extends in the extending direction of the looping wire 50. In FIGS. 3 and 4, the height of the column-like bump 45 is set as a height substantially equal to the height of the adjacent second electronic component 32b. Nevertheless, the height of the column-like bump 45 may also be set lower, such as a height about 50% of the height of the adjacent second electronic component 32b. In addition, the height of the column-like bump 45 may also exceed the height of the adjacent second electronic component 32b.

Referring to FIG. 2 again, the looping wire 50 is bonded to the first bond point P1 of the first pad 33 and the second bond point P2 of the second pad 34 to stride over the first to third electronic components 32a to 32c. The looping wire 50 extends in the front-rear direction and includes a press-bonded ball 51, a first raised part 53, a second raised part 54, a loop part 55, a bent part 56, and a stitch-bonded part 57.

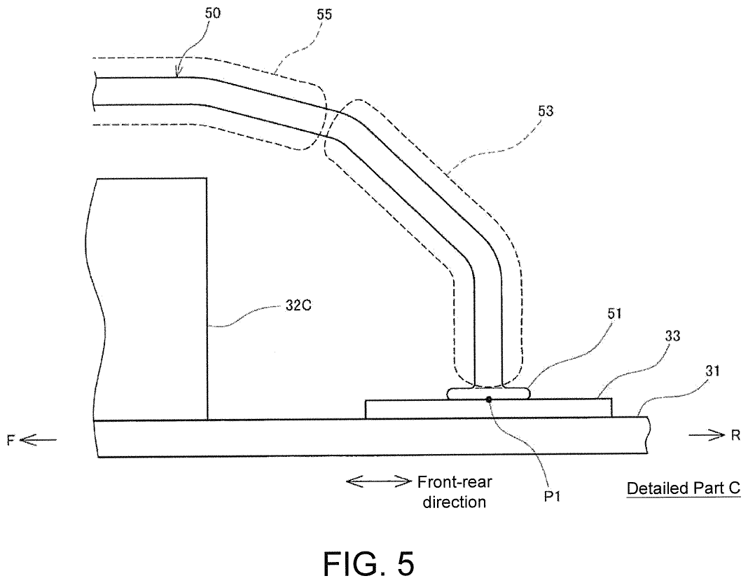

As shown in FIG. 5, the press-bonded ball 51 is a disk-shaped portion in which an air free ball 40 is bonded onto the first pad 33. The first raised part 53 is a portion extending upward from the top of the press-bonded ball 51 and then bent forward to extend to the vicinity of the upper side of the third electronic component 32c.

As shown in FIG. 2, the loop part 55 is a portion connected to the first raised part 53 and extending in the front-rear direction to stride over the first to fourth electronic components 32a to 32d.

As shown in FIG. 3, the second raised part 54 is a portion raised obliquely upward from the stitch-bonded part 57 stitch-bonded onto the second pad 34. The bent part 56 is a portion bent to be engaged with the groove 48 formed at the upper end of the column-like bump 45 and extending in the front-rear direction to connect the loop part 55 and the second raised part 54. A bent angle θ of the bent part 56 as shown in FIG. 3 may range from 60° to 90°.

In the electronic apparatus 30 as configured above, since the bent part 56 of the looping wire 50 is engaged with the groove 48 provided at the upper end of the column-like bump 45 to be bent, the bent angle θ of the bent part 56 can be increased. Accordingly, the second raised part 54 can be raised at a nearly vertical angle from the second pad 34 of the substrate 31. Therefore, even if the tip of the second raised part 54 is stitch-bonded to a position adjacent to the second electronic component 32a, the upper part of the second raised part 54 or the bent part 56 can be suppressed from contacting the adjacent second electronic component 32b, and the first to fourth electronic components 32a to 32d can be magnetically shielded by using less space.

In the electronic component 30 of the embodiment described above, the looping wire 50 is bonded onto the first pad 33 and the second pad 34, and the looping wire 50 extends in the front-rear direction to stride over the first to fourth electronic components 32a to 32d. However, the invention is not limited thereto. For example, the looping wire 50 may also be bonded onto the left-side pad 35 and the right-side pad 36 to extend in the left-right direction. In addition, the looping wire 50 may also be bonded between the first pad 33 and the left-side pad 35 or the right-side pad 36 to extend in an oblique direction.

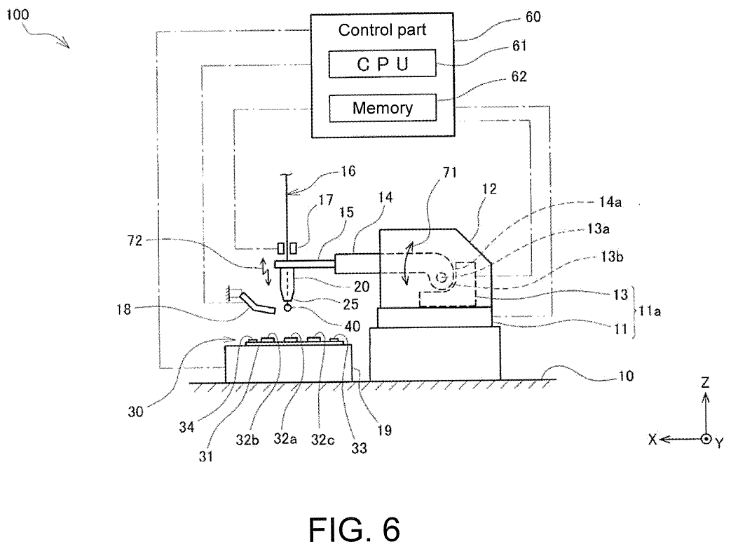

In addition, a method for forming the wire structure 50A installed to the electronic apparatus 30 is described with reference to FIGS. 6 to 11C. Firstly, a wire bonding apparatus 100 is described. The wire bonding apparatus 100 is an apparatus for manufacturing the electronic apparatus 30.

As shown in FIG. 6, the wire bonding apparatus 100 includes a base 10, an XY table 11, a bonding head 12, a Z-direction motor 13, a bonding arm 14, an ultrasonic horn 15, a capillary 20 as a wire bonding tool, a wire clamper 17, a discharge electrode 18, a bonding stage 19, and a control part 60. In the following description, an extending direction of the bonding arm 14 or the ultrasonic horn 15 is set as the X direction, a direction orthogonal to the X direction on a horizontal plane is set as the Y direction, and the upper-lower direction is set as the Z direction.

The XY table 11 is installed to the base 10 to move an object mounted to the upper side in the XY directions.

The bonding head 12 is installed to the top of the bonding table 11 to be moved in the XY directions by the XY table 11. The Z-direction motor 13 and the bonding arm 14 driven by the Z-direction motor 13 are stored in the bonding head 12. The Z-direction motor 13 includes a stator 13b. A root part 14a of the bonding arm 14 faces the stator 13b of the Z-direction motor 13 and serves as a rotor installed to be rotatable around a shaft 13a of the Z-direction motor 13.

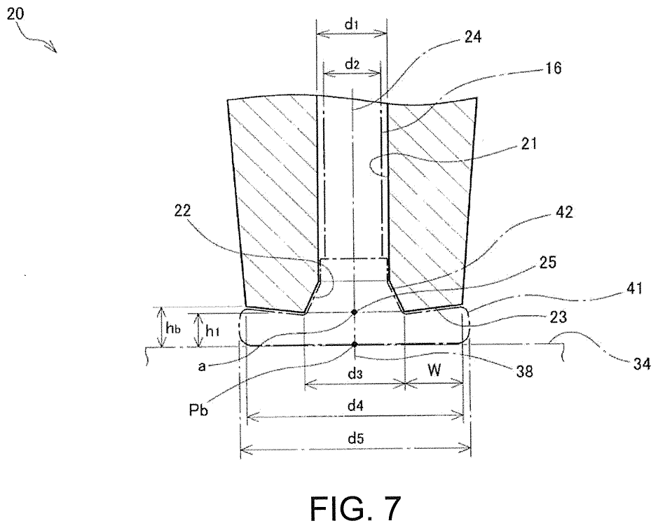

The ultrasonic horn 15 is installed to the tip of the bonding arm 14 in the X direction, and the capillary 20 is installed to the tip of the ultrasonic horn 15. The ultrasonic horn 15 ultrasonically vibrates the capillary 20 installed to the tip through the vibration of an ultrasonic vibrator not shown herein. As will be described in the following with reference to FIG. 7, a through hole 21 penetrating in the upper-lower direction is provided inside the capillary 20, and a wire 16 is inserted through the through hole 21. The wire 16 is supplied from a wire supply such as a wire spool not shown herein.

In addition, the wire clamper 17 is provided on the upper side of the tip of the ultrasonic horn 15. The clamper 17 is opened or closed to grip or release the wire 16.

The discharge electrode 18 is provided on the upper side of the bonding stage 19. The discharge electrode 18 may also be installed to a frame provided at the base 10 and not shown herein. The discharge electrode 17 performs discharging with respect to the wire 16 inserted into the capillary 20 and extending from a tip 25 of the capillary 20, melts the wire 16 to form the air free ball 40.

The bonding stage 19 absorbs and fixes, to the top surface thereof, the substrate 31 in which the first to fourth electronic components 32a to 32d are installed and heats the substrate 31 by using a heater not shown herein.

When the root part 14a of the bonding arm 14 forming the rotor is rotated as indicated by an arrow 71 in FIG. 6 through an electromagnetic force of the stator 13b of the Z-direction motor 13 of the bonding head 12, the capillary 20 installed to the tip of the ultrasonic horn 15 moves in the Z direction as indicated by an arrow 72. In addition, the bonding stage 19 is moved in the XY directions by the XY table 11. Accordingly, the capillary 20 moves in the XYZ directions by the XY table 11 and the Z-direction motor 13. In addition, the wire clamper 17 moves with the capillary 20 in the XYZ directions. Accordingly, the XY table 11 and the Z-direction motor 13 form a movement mechanism 11 a moving the capillary 20 and the wire clamper 17 in the XYZ directions.

The XY table 11, the Z-direction motor 13, the wire clamper 17, the discharge electrode 18, and the bonding stage 19 are connected to the control part 60 and operated based on the command of the control part 60. The control part 60 adjusts the position of the capillary 20 in the XYZ directions through the movement mechanism 11 a configured by the XY table 11 and the Z-direction motor 13, and performs control to open/close the wire clamper 17, to drive the discharge electrode 18, and to heat the bonding stage 19.

The control part 60 is a computer including a CPU 61, which is a processor performing information processing internally, and a memory 62 storing an operation program, operation data, etc.

In the following, the structure of the capillary 20 is described with reference to FIG. 7. FIG. 7 is a view illustrating an example of the tip part of the capillary 20. The through hole 21 penetrating in the direction of a center line 24 passing through a center position is formed in the capillary 20. The wire 16 is inserted into the through hole 21. Therefore, an inner diameter d1 of the through hole 21 is greater than an outer diameter d2 of the wire 16 (d1>d2). The lower end of the through hole 21 extends in a conical shape. Such tapered part extending in a conical shape is referred to as a chamfer part 22. In addition, the maximum diameter (i.e., the diameter at the lowermost end) in the space of the conical shape is referred to as a chamfer diameter d3.

The lower end surface of the capillary 20 serves as a ring-shaped face part 23 pressing the air free ball 40 shown in FIG. 6. The face part 23 may be a flat, horizontal plane, and may also be a surface inclined upward toward the outer side. The width of the face part 23, that is, a distance between the chamfer part 22 and the outer periphery of the lower end of the capillary 20, is referred to as a face width W. The face width W is calculated by using W=(d4−d3)/2 in accordance with the chamfer diameter d3 and an outer peripheral diameter d4 of the capillary 20. Moreover, in the following description, a point of the lower end of the capillary 20 on the center line 24 is referred to as the tip 25 of the capillary 20.

As indicated by the dot-chain line in FIG. 7, when the tip 25 of the capillary 20 is lowered to a point a of a height hl to press the air free ball 40 as shown in FIG. 6 onto the second pad 34, the air free ball 40 is pressed by the face part 23 and flattened to form the press-bonded ball 41 in a flat, cylindrical columnar shape with a diameter d5 and a thickness hb. Then, a portion of the metal forming the air free ball 40 enters the through hole 21 from the chamfer part 22, and a ball neck 42 connected to the upper side of the press-bonded ball 41 is formed.

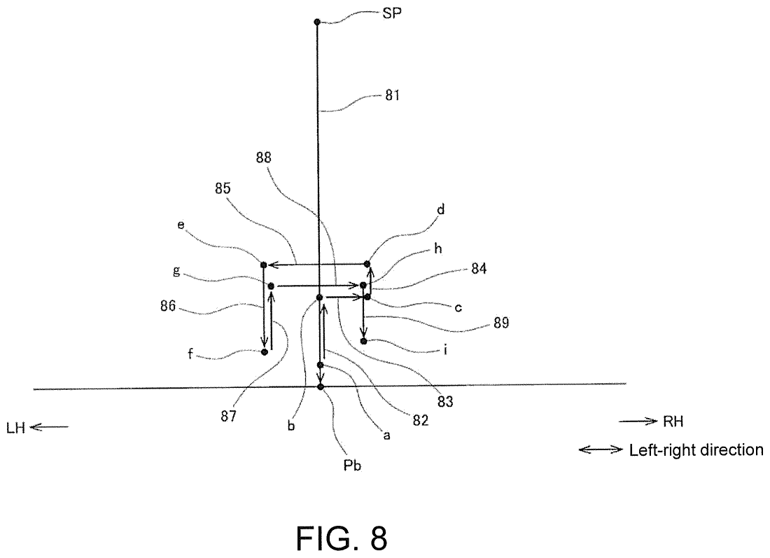

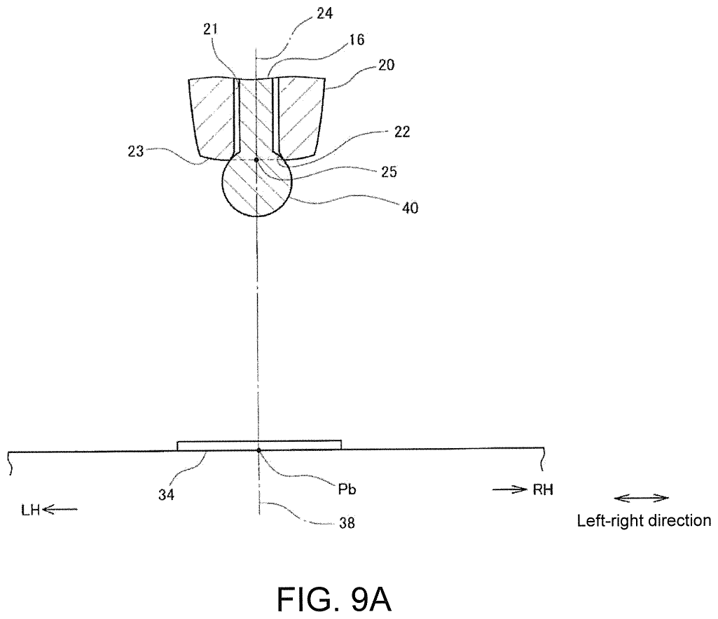

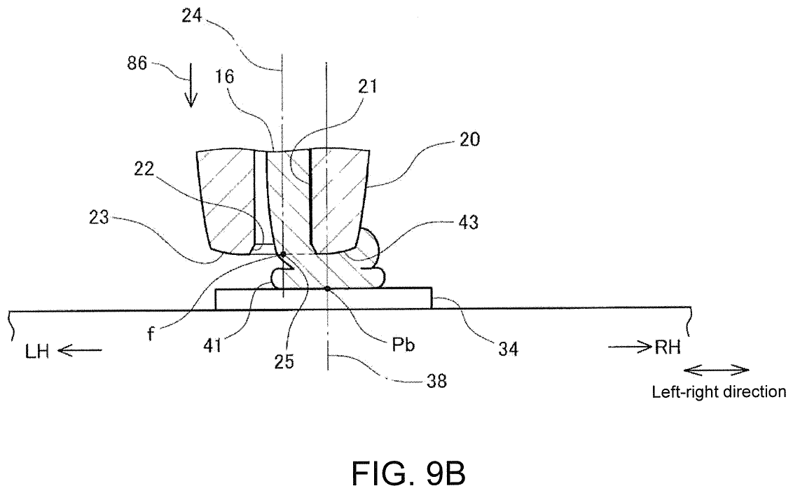

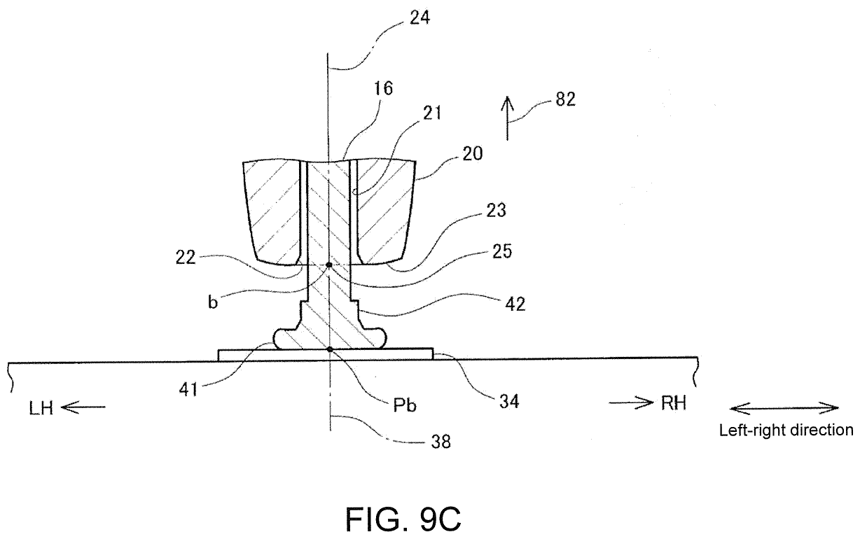

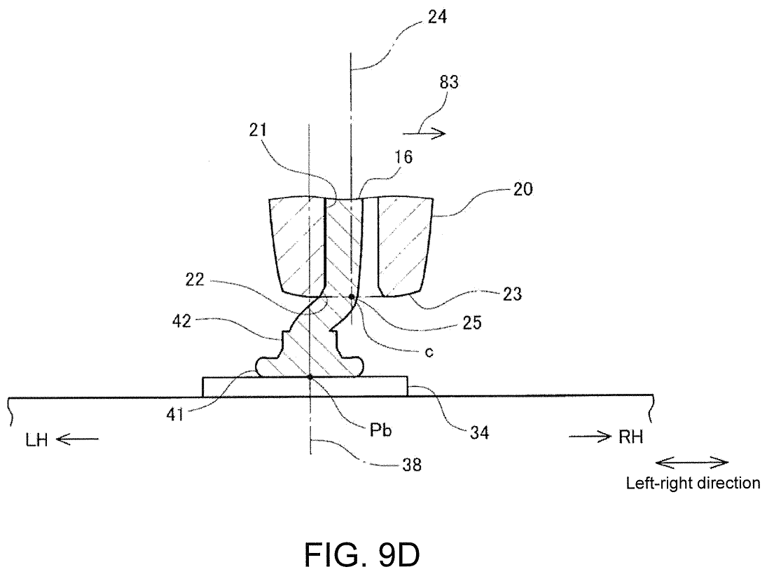

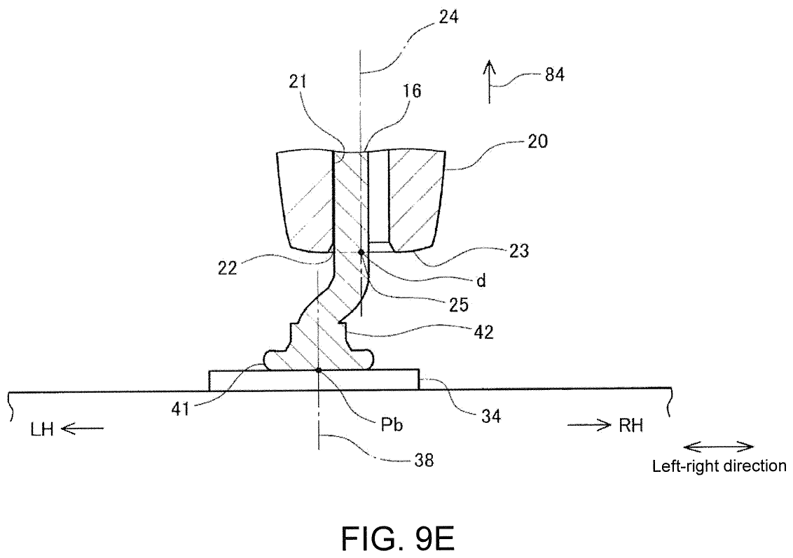

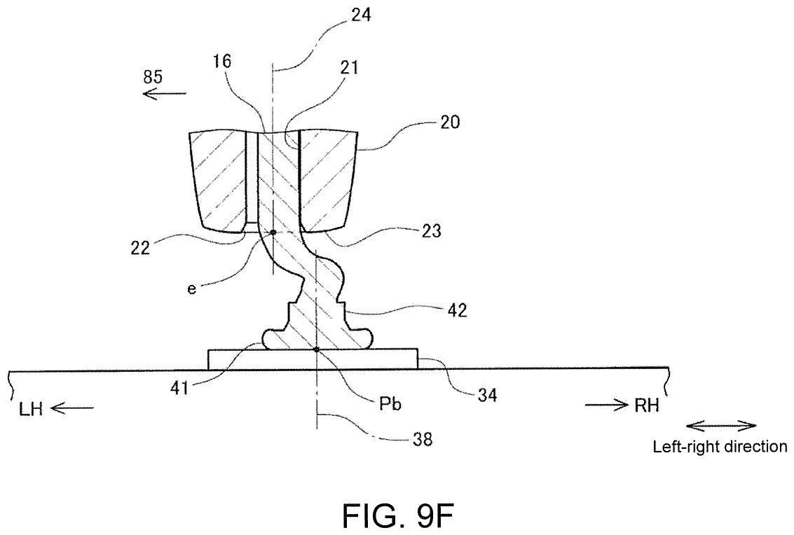

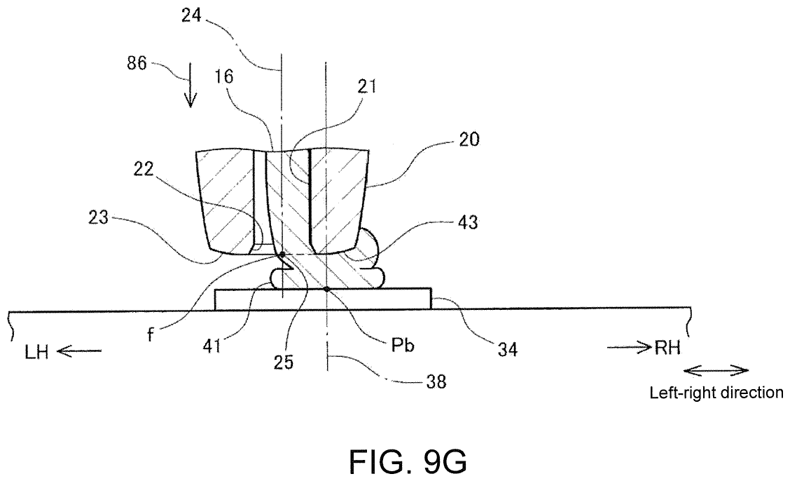

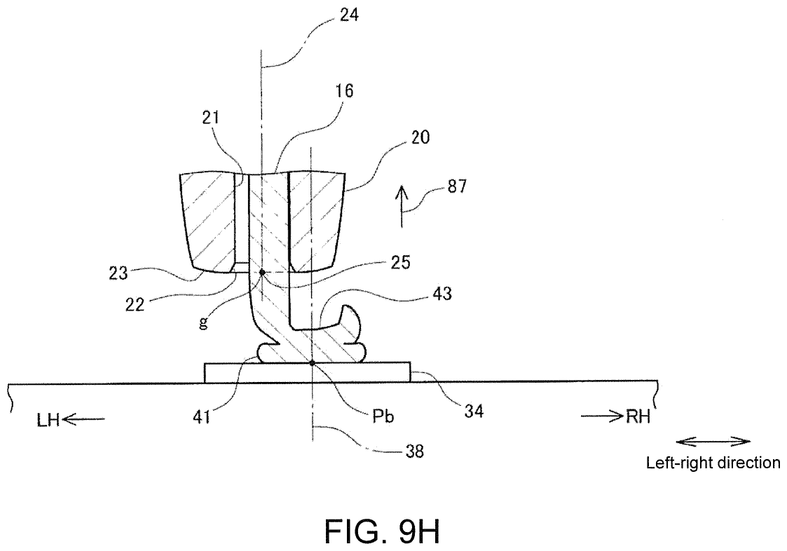

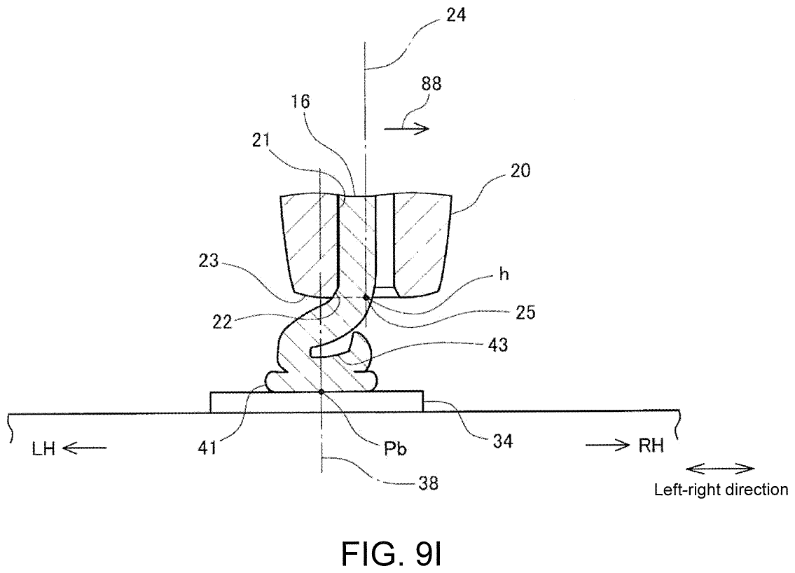

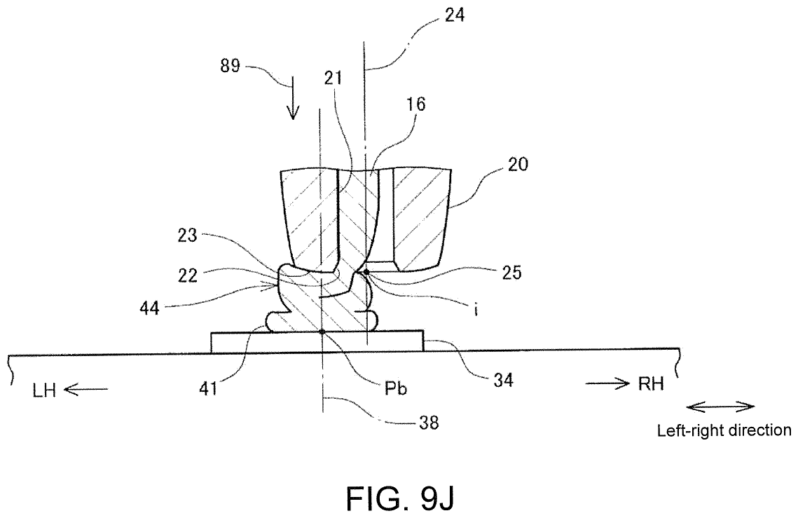

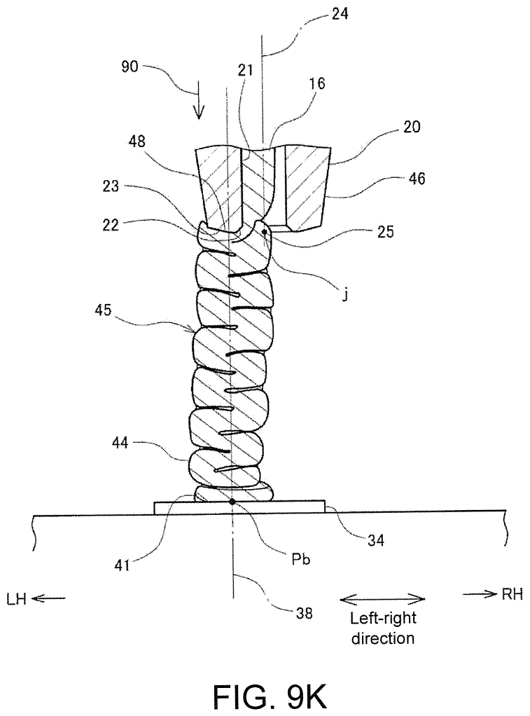

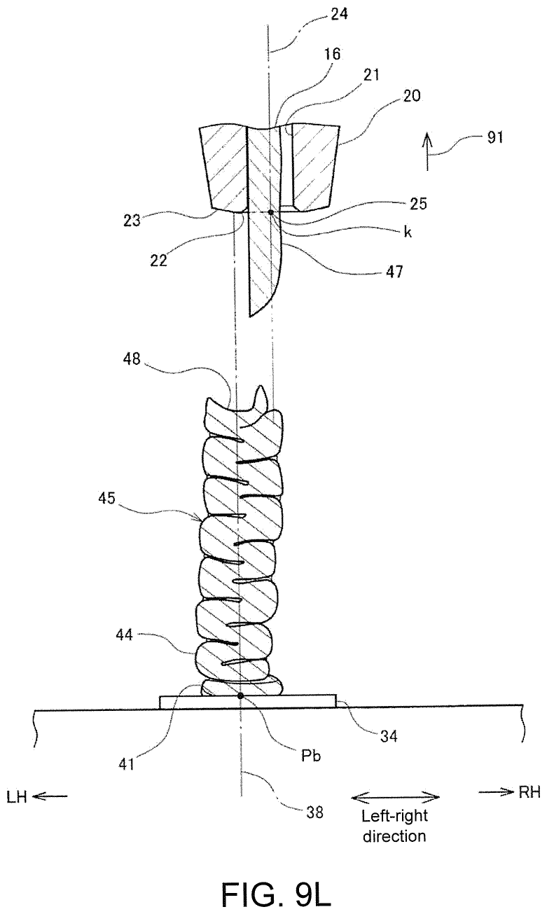

In the following, a column-like bump forming process in which the column-like bump 45 is formed on the second pad 34 is described with reference to FIGS. 8 to 9L.

Firstly, the CPU 61, which is the processor of the control part 60, opens the wire clamper 17, and performs driving control on the XY table 11 and the Z-direction motor 13 to move the tip 25 of the capillary 20 to the vicinity of the discharge electrode 18. Then, the CPU 61 generates discharge between the discharge electrode 18 and the wire tail extending from the tip 25 of the capillary 20, and, as shown in FIG. 9A, molds the wire 16 extending from the tip 25 of the capillary 20 into the air free ball 40.

Then, as shown in FIGS. 8 and 9A, the CPU 61 performs driving control on the XY table 11 and the Z-direction motor 13 to fit the XY coordinates of the center line 24 of the capillary 20 to the XY coordinates of a center line 38 of the bump point Pb on the second pad 34. Then, as indicated by an arrow 81 shown in FIGS. 8 and 9B, the CPU 61 lowers the tip 25 of the capillary 20 toward the bump point Pb until the point a, and, as shown in FIG. 9B, performs ball-bonding which presses the air free ball 40 onto the second pad 34 by using the face part 23 of the capillary 20.

When the capillary 20 presses the air free ball 40 onto the second pad 34, as described with reference to FIG. 2, the face part 23 and the chamfer part 22 mold the air free ball 40 into the press-bonded ball 41 and the ball neck 42.

Then, as shown in FIGS. 8 and 9C, the CPU 61 performs driving control on the XY table 11 and the Z-direction motor 13 to raise the tip 25 of the capillary 20 to a point b as indicated by an arrow 82 shown in FIGS. 8 and 9C. Then, the CPU 61 laterally moves the tip 25 of the capillary 20 rightward to a point c as indicated by an arrow 83 shown in FIGS. 8 and 9D. Then, the CPU 61 raises the tip 25 of the capillary 20 to a point d as indicated by an arrow 84 shown in FIGS. 8 and 9E. Then, the CPU 61 laterally moves the capillary 20 leftward to a position where the center of the face part 23 on the right side of the capillary 20 in a face width direction is at the XY coordinates of the center line 38 of the bump point Pb, as indicated by an arrow 85 shown in FIGS. 8 and 9F.

As indicated by the arrows 82 to 85, the tip 25 of the capillary 20 is raised and then laterally moved rightward. Then, the capillary 20 is again raised and moved leftward. Accordingly, as shown in FIG. 9F, the wire 16 on the upper side of the ball neck 42 is in a shape of being wrapped back rightward and leftward on the ball neck 42.

Then, the CPU 61 performs driving control on the XY table 11 and the Z-direction motor 13 to lower the tip 25 of the capillary 20 to a point f, as indicated by an arrow 86 shown in FIGS. 8 and 9G, and press the side surface of the wire 16 wrapped back rightward and leftward on the ball 42 onto the ball neck 42 to form a crushed part 43.

Then, as indicated by an arrow 87 shown in FIGS. 8 and 9H, the CPU 61 raises the tip 25 of the capillary 20 to a point g, and then, as indicated by an arrow 88 shown in FIGS. 8 and 9I, laterally moves the capillary 20 rightward to a position where the center of the face part 23 on the left side of the capillary 20 in the face width direction is at the XY coordinates of the center line 38 of the bump point Pb.

By raising and laterally moving the capillary 20 rightward, the wire 16 raised upward from the left side of the crushed part 43 shown in FIG. 9H is folded on the upper side of the crushed part 43.

Then, the CPU 61 performs driving control on the XY table 11 and the Z-direction motor 13 to lower the tip 25 of the capillary 20 to a point i, and, as indicated by an arrow 89 shown in FIGS. 8 and 9J, and press the side surface of the wire 16 onto the crushed part 43 to form the folded part 44.

Then, the CPU 61 performs driving control on the XY table 11 and the Z-direction motor 13 to raise the capillary 20 and, as shown in FIGS. 9H to 9J, alternately fold the side surface of the wire 16 from the left and the right to mold the folded part 44 in multiple segments and form the column-like bump 45. Then, the CPU 61 moves the capillary 20 to the position where the center of the face part 23 on the left side of the capillary 20 in the face width direction is at the XY coordinates of the center line 38 of the bump point Pb, and, as indicated by an arrow 90 shown in FIG. 9K, lowers the tip 25 of the capillary 20 to a point j and presses the side surface of the wire 16 onto the folded part 44 to form the folded part 44 of the uppermost segment. Through such pressing, the groove 48 extending in the front-rear direction is formed on the upper surface of the folded part 44 of the uppermost segment by using the face part 23. At this time, the folded part 44 of the uppermost segment and the wire 16 entering the through hole 21 of the capillary 20 are linked by a thin connection part 46.

Then, the CPU 61 performs driving control on the XY table 11 and the Z-direction motor 13t to, as indicated by an arrow 91 shown in FIG. 9L, raise the capillary 20 to extend a wire tail 47 from the tip 25 of the capillary 20. Then, the CPU 61 closes the wire clamper 17 to further raises the wire clamper 17 and the capillary 20, thereby cutting off the lower end of the wire tail 47 and the connection part 46 connected to the wire supply. Accordingly, as shown in FIG. 9L, the column-like bump 45 is formed on the second pad 34.

As described above, by repetitively raising the capillary 20, moving the capillary 20 in the left-right direction, and pressing by lowering the capillary 20, the folded part 44 can be molded into multiple segments by alternately folding the side surface of the wire 16 from the left and the right, and the column-like bump 45 can be formed. In addition, at the time of molding the folded part 44 of the uppermost segment, the position of the center line 24 of the capillary 20 is deviated rightward with respect to the position of the center line 38 of the column-like bump 45 to press the side surface of the wire 16, so that the center of the face part 23 on the left side of the capillary 20 in the face width direction is at the XY coordinates of the center line 38 of the bump point Pb. That is, the position of the center line 24 of the capillary 20 is deviated, with respect to the position of the center line 38 of the column-like bump 45, in the left-right direction intersecting the front-rear direction that is the extending direction of the loop part 55 to press the side surface of the wire 16. Accordingly, the groove 48 extending in the front-rear direction can be formed at the upper end of the column-like bump 45.

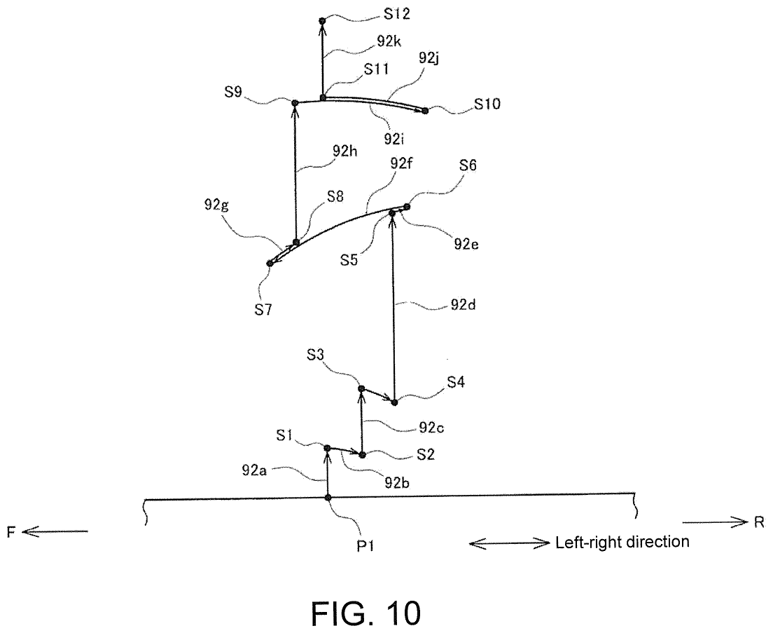

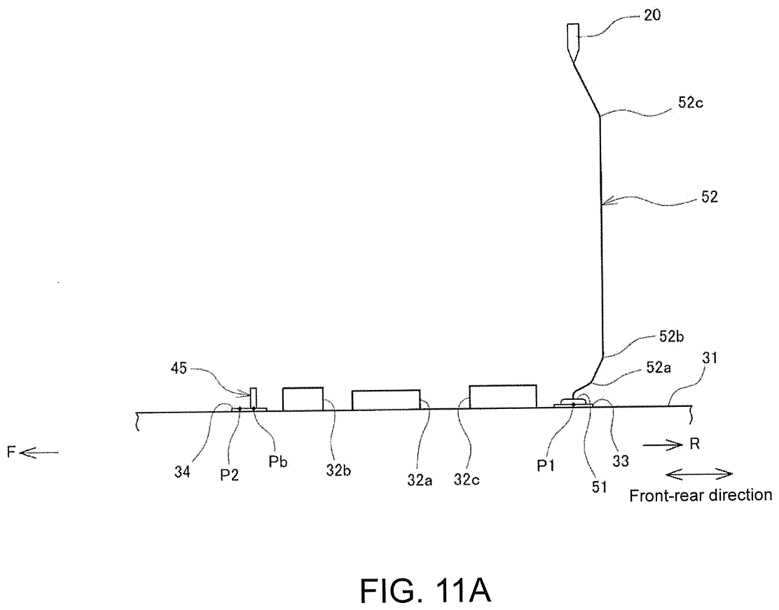

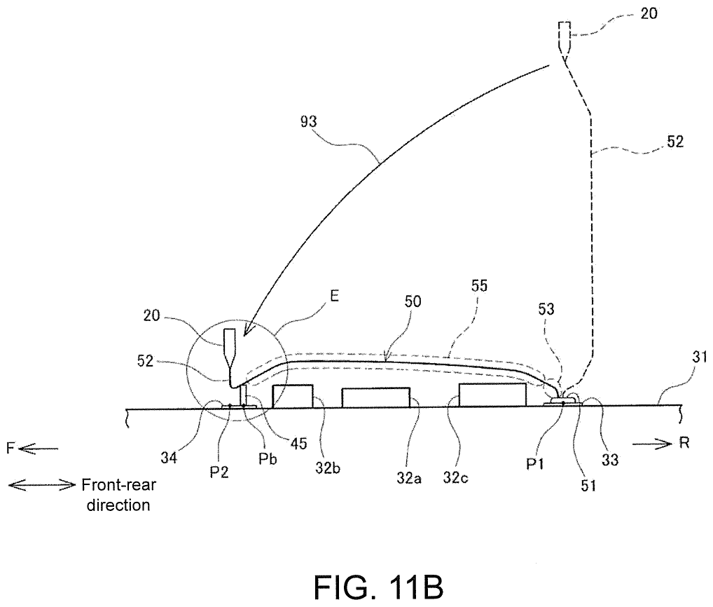

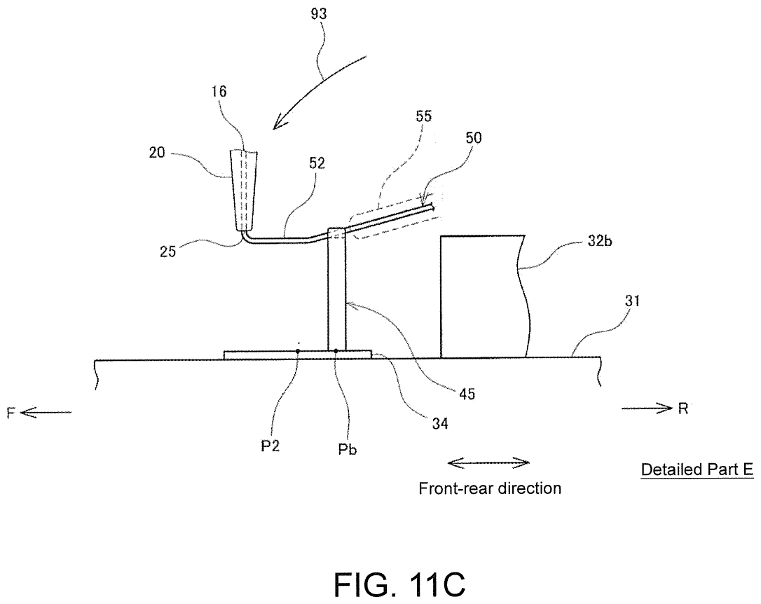

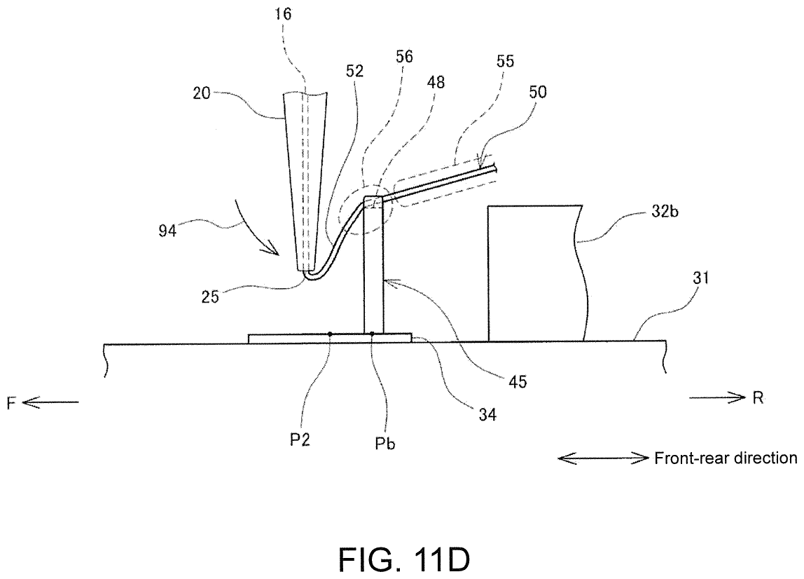

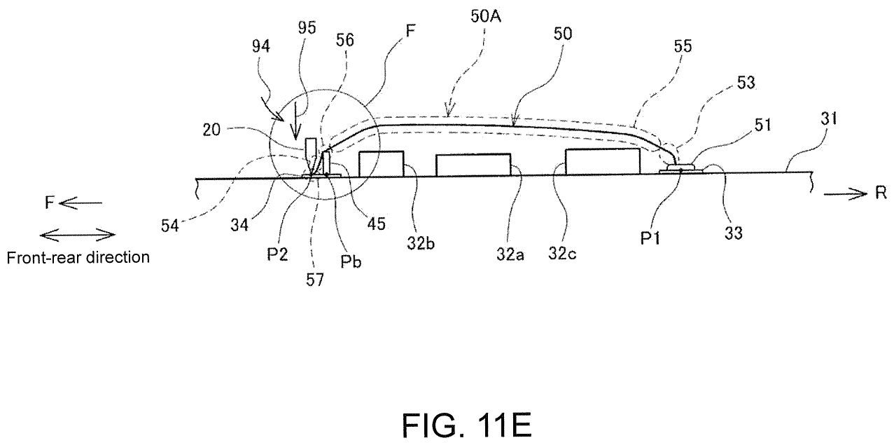

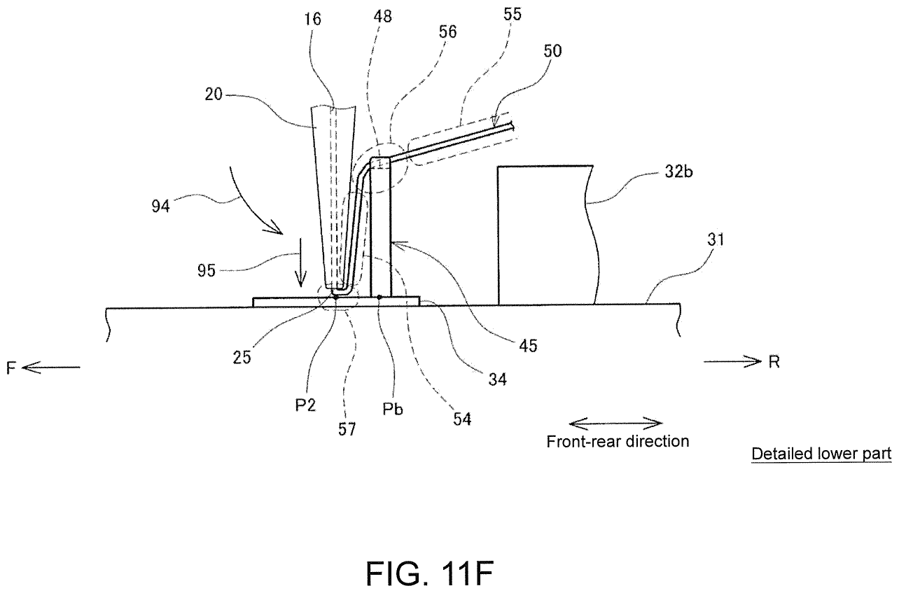

Then, a process of forming the looping wire 50 is described with reference to FIGS. 10 to 11C.

The CPU 61 of the control part 60 performs driving control on the XY table 11 and the Z-direction motor 13 to, as described with reference to FIGS. 9A and 9B, form the air free ball 40 at the tip of the wire, and, as shown in FIG. 11A, lower the capillary 20 onto the first pad 33 to form the press-bonded ball 51 on the first pad 33 (first bonding process).

Then, the CPU 61 performs driving control on the XY table 11 and the Z-direction motor 13 to, as indicated by arrows 92a to 92k of FIG. 10, repetitively raise the capillary 20 and move the capillary 20 in the front-rear direction 20 to pass through respective points S1 to S12 from the first bond point P1 to form a kink wire 52 having a first kink 52a, a second kink 52b, and a third kink 52c as shown in FIG. 11A (kink wire formation process).

Then, as indicated by an arrow 93 of FIG. 11B, the CPU 61 loops the tip 52 of the capillary 20 toward the upper end of the column-like bump 45 to form the loop part 55 of the looping wire 50 striding over the first to third electronic components 32a to 32c between the first bond point P1 and the upper end of the column-like bump 45 (loop part formation process). At this time, a portion including the first kink 52a and the second kink 52b of the kink wire 52 raises from the top of the press-bonded ball 51 on the first pad 33, as shown in FIGS. 5 and 11B, to be molded into the first raised part 53 of the looping wire 50 toward the upper side of the third electronic component 32c. In addition, as shown in FIG. 11C, when the side surface of the kink wire 52 contacts the upper end of the column-like bump 45 to form the loop part 55 of the looping wire 50, the tip 25 of the capillary 20 and a tip portion of the kink wire 52 is located at the front with respect to the column-like bump 45.

Then, the CPU 61 performs driving control on the XY table 11 and the Z-direction motor 13 to, as indicated by an arrow 94 of FIG. 11D, move the tip 25 of the capillary 20 downward in an arc shape toward the second bond point P2. Accordingly, the tip 25 of the capillary 20 engages the side surface of the kink wire 52 to the groove 48 at the upper end of the column-like bump 45 and bends the front side of the portion of the kink wire 52 engaged with the groove 48 toward the second pad 34 of the substrate 31 to form the bent part 56 of the looping wire 50 (bent part formation process).

Then, the CPU 61 performs driving control on the XY table 11 and the Z direction motor 13 to, as indicated by an arrow 94 of FIGS. 11E and 11F, move the tip 25 of the capillary 20 downward in an arc shape toward the second bond point P2, and, as indicated by an arrow 95 of FIGS. 11E and 11F, lower the tip 25 of the capillary 20 toward the second bond point P2 to stitch-bond the tip part of the kink wire 52 onto the second bond point P2 on the second pad 34. Accordingly, the stitch-bonded part 57 of the looping wire 50 and the second raised part 54 of the looping wire 50 raised from the stitch-bonded part 57 to be connected to the bent part 56 are formed on the second pad 34 (raised part formation process).

Then, the CPU 61 closes the wire clamper 17 to further raises the wire clamper 17 and the capillary 20, thereby cutting off the wire 16 and the stitch-bonded part 57 connected to the wire supply. Accordingly, the formation of the looping wire 50 is completed.

As described above, after the column-like bump 45 is formed, the kink wire 52 loops until the upper end of the column-like bump 45 to engage the side surface of the kink wire 52 to the groove 48 at the upper end of the column-like bump 45, thereby bending the kink wire 52. Therefore, the bent part 56 with a large bent angle θ can be formed, and the second raised part 54 can be raised at a nearly vertical angle from the second pad 34 of the substrate 31. Accordingly, even if the tip of the second raised part 54 is bonded to a position adjacent to the second electronic component 32b, the upper part of the second raised part 54 or the bent part 56 can be suppressed from contacting the second electronic component 32b, and the wire structure 50A enabling magnetic shielding for the first to fourth electronic components 32a to 32d can be formed by using less space.

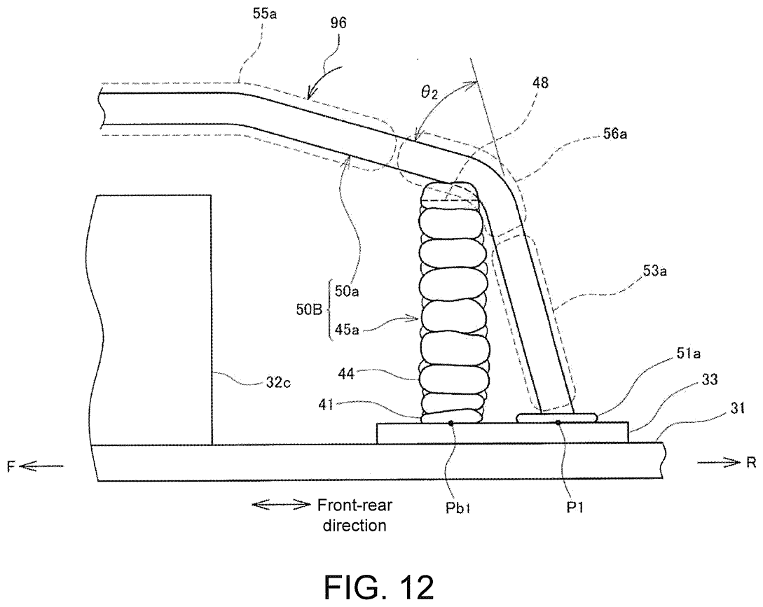

In the following, a wire structure 50B according to another embodiment is described with reference to FIG. 12. As shown in FIG. 12, the wire structure 50B is formed by a column-like bump 45a and a looping wire 50a.

The column-like bump 45a is formed on a bump point Pb1 arranged on the side of the second bond point P2 with respect to the first bond point P1 on the first pad 33. The column-like bump 45a, like the column-like bump 45 described with reference to FIGS. 1 to 9L, includes the press-bonded ball 41 and the folded part 44 of multiple segments, and the groove 48 extending in the front-rear direction is provided at the upper end.

The looping wire 50a, like the looping wire 50 described with reference to FIGS. 1 to 9L, is bonded onto the substrate 31 to be connected with the first pad 33 and the second pad 34, so as to stride over the first to fourth electronic components 32a to 32d. The looping wire 50a differs from the looping wire 50a in that the side of the first pad 33 is formed by a press-bonded ball 51a, a first raised part 53a, a bent part 56a, and a loop part 55a. The rest of the configuration is the same as the looping wire 50a as described.

As shown in FIG. 12, the first raised part 53a is a portion raised obliquely upward from the press-bonded ball 51a on the first pad 33. The bent part 56a is a portion connected with the first raised part 53a and bent toward the top of the third electronic component 32c from a rising direction at the top end of the column-like bump 45. A bent angle θ2 of the bent part 56a may range from 60° to 90°. The loop part 55a is a portion connected to the bent part 56a and striding over the first to third electronic components 32a to 32c from a vertical direction at the upper end of the column-like bump 45a to extend to the second bond point P2.

In the case of forming the wire structure 50B shown in FIG. 12, firstly, the column-like bump 45, 45a is formed on the bump point Pb, Pb1 of the first pad 33, the second pad 34 by using the same method with reference to FIGS. 9A to 9L (column-like bump generation process).

Then, as described with reference to FIG. 11A, ball-bonding is performed at the first bond point P1 to form the press-bonded ball 51 (first bonding process). Then, the capillary 20 is raised and the wire 16 is unwound from the tip 25 of the capillary 20, and the capillary 20 is laterally moved to form the kink wire 52 (kink wire formation process). At this time, the winding angle of the first kink 52a shown in FIG. 11A may be smaller than the case of forming the wire structure 50A, or the first kink wire 52a may be omitted to form only the second and third kinks 52b and 52c.

Then, as indicated by an arrow 96 shown in FIG. 12, the capillary 20 loops toward the upper end of the column-like bump 45 formed on the second pad 34. At this time, the side surface of the kink wire 52 is engaged with the groove 48 formed at the upper end of the column-like bump 45a on the first pad 33, and the kink wire 52 is bent by the bent angle θ2 toward the top of the third electronic component 23c to form the bent part 56a. In addition, the loop part 55a connected to the bent part 56a to extend toward the second bond point P2 is formed. Accordingly, the bent part 56a is a portion bent to be engaged with the upper end of the column-like bump 45a to connect the loop part 55a and the first raised part 53a.

After the side surface of the loop part 55a contacts the column-like bump 45 formed on the second pad 34, as described with reference to FIGS. 11B to 11F, the bent part generation process and the raised part formation process are executed to form the looping wire 50a.

In the wire structure 50B shown in FIG. 12, even if the press-bonded ball 51a of the looping wire 50a is bonded to a position adjacent to the third electronic component 32c provided on the side of the first pad 33, the upper part of the first raised part 53a or the bent part 56a can be suppressed from contacting the third electronic component 32c, and the space for forming the looping wire 50a on the side of the first pad 33 can be reduced. Accordingly, the magnetic shielding for the first to fourth electronic components 32a to 32d can be realized by using less space.

### REFERENCE SIGNS LIST

10: Base; 11: XY table; 11a: Movement mechanism; 12: Bonding head; 13: Z-direction motor; 13a: Shaft; 13b: Stator; 14: Bonding arm; 14a: Root part; 15: Ultrasonic horn; 16: Wire; 17: Wire damper; 18: Discharge electrode; 19: Bonding stage; 20: Capillary; 21: Through hole; 22: Chamfer part; 23: Face part; 24, 38: center line; 25: Tip; 30: Electronic apparatus; 31: Substrate; 32a: First electronic component; 32b: Second electronic component; 32c: Third electronic component; 32d: Fourth electronic component; 33: First pad; 34: Second pad; 35: Left-side pad; 36: Right-side pad; 40: Air free ball; 41, 51: Press-bonded ball; 42: Ball neck; 43: Crushed part; 44: Folded part; 45, 45a: Column-like bump; 46: Connection part; 47: Wire tail; 48: Groove; 50, 50a: Looping wire; 50A, 50B: Wire structure; 52: Kink wire; 52a to 52c: first to third kinks; 53, 53a: First raised part; 54: Second raised part; 55, 55a: Loop part; 56, 56a: Bent part; 57: Stitch-bonded part; 60: Control part; 61: CPU; 62: Memory; 100: Wire bonding apparatus.

1. A wire structure, comprising:
a column-like bump, formed on a bump point provided to be adjacent to an electronic component installed on a substrate; and
a looping wire, bonded onto the substrate between a first bond point and a second bond point, so as to stride over the electronic component, wherein the first bond point is provided on the substrate to sandwich the electronic component with the bump point, and the second bond point is provided to be adjacent to a side opposite to the first bond point with respect to the bump point on the substrate,
wherein the looping wire comprises:
a raised part, wherein a tip is bonded to the substrate at the second bond point to be raised from the substrate;
a loop part, extending to stride over the electronic component; and
a bent part, bent to be engaged with an upper end of the column-like bump to connect the loop part and the raised part,
wherein the bump point and the second bond point are provided on a common pad, and
wherein the column-like bump has a column shape formed by a press-bonded ball formed on the pad and a folded part of a plurality of segments formed on the press-bonded ball, and an upper end of the column-like bump has a groove extending in an extending direction of the loop part, and the bent part is engaged with the groove.

2. (canceled)

3. The wire structure as claimed in claim 1, wherein the bent part has a bent angle ranging from 60° to 90°.

4. The wire structure as claimed in claim 1, wherein a height of the column-like bump is equal to or greater than a height of the electronic component.

5. A wire structure formation method for forming a wire structure comprising a column-like bump and a looping wire by using a bonding tool, the wire structure formation method comprising:
a column-like bump formation process of folding multiple times and pressing a wire, by using the bonding tool, to a bump point on a substrate to form a column shape,
thereby forming the column-like bump;
a first bonding process of bonding the wire, by using the bonding tool, onto a first bond point arranged on the substrate to sandwich an electronic component with the bump point;
a kink wire formation process of, after the first bonding process, raising the bonding tool to unwind the wire from a tip of the bonding tool, and moving the bonding tool laterally to form a kink wire comprising at least one kink;
a loop part formation process of, after the kink wire formation process, looping the bonding tool toward an upper end of the column-like bump to form a loop part striding over the electronic component between the first bond point and the upper end of the column-like bump;
a bent part formation process of, after the loop part formation process, engaging a side surface of the kink wire to the upper end of the column-like bump to bend the kink wire toward the substrate, thereby forming a bent part; and
a raised part formation process of, after the bent part formation process, bonding the kink wire, by using the bonding tool, to a second bond point adjacent to a side opposite to the first bond point with respect to the bump point and provided on the substrate, and forming a raised part raised from the second bond point to be connected with the bent part.

6. The wire structure formation method as claimed in claim 5, wherein the bonding tool is a capillary comprising a through hole into which the wire is inserted and a ring-shaped face part provided on a periphery of the through hole,
wherein in the column-like bump formation process, at a time of folding a side surface of the wire to form a folded part of an uppermost segment, a center position of the capillary is deviated in a direction intersecting with an extending direction of the loop part to press the side surface of the wire by using the face part, and a groove extending in the extending direction of the loop part is formed at the upper end of the column-like bump.

7. The wire structure formation method as claimed in claim 6, wherein in the bent part formation process, a side surface of the kink wire is engaged with the groove to bend the kink wire toward the substrate by using the bonding tool.

8. The wire structure formation method as claimed in claim 5, wherein in the first bonding process, ball-bonding is performed on the wire at the first bond point, and
in the raised part formation process, stitch-bonding is performed at the second bond point.

9. The wire structure formation method as claimed in claim 5, wherein in the column-like formation process, another column-like bump is further formed at another bump point arranged between the first bond point and the electronic component; and
in the loop part formation process, after the kink wire formation process, when the bonding tool loops toward the upper end of the column-like bump to form the loop part striding over the electronic component between the first bond point and the upper end of the column-like bump, a side surface of the kink wire is engaged with an upper end of the another column-like bump to bend the kink wire toward a top of the electronic component, thereby forming another bent part.

10. An electronic apparatus, comprising:
a substrate;
an electronic component installed on the substrate;
a column-like bump, formed on a bump point provided to be adjacent to the electronic component; and
a looping wire, bonded onto the substrate between a first bond point and a second bond point, so as to stride over the electronic component, wherein the first bond point is provided on the substrate to sandwich the electronic component with the bump point, and the second bond point is provided to be adjacent to a side opposite to the first bond point with respect to the bump point on the substrate,
wherein the looping wire comprises:
a raised part, wherein a tip is bonded to the substrate at the second bond point to be raised from the substrate;
a loop part, extending to stride over the electronic component; and
a bent part, bent to be engaged with an upper end of the column-like bump to connect the loop part and the raised part,
wherein the bump point and the second bond point are provided on a common pad, and
wherein the column-like bump has a column shape formed by a press-bonded ball formed on the pad and a folded part of a plurality of segments formed on the press-bonded ball, and an upper end of the column-like bump has a groove extending in an extending direction of the loop part, and the bent part is engaged with the groove.

11. The electronic apparatus as claimed in claim 10, wherein a height of the column-like bump is equal to or greater than a height of the electronic component.
